(19) United States
(12) Patent Application Publication
(10) Pub. No.: US 2026/0121583 A1
(43) Pub. Date: Apr. 30, 2026

(54) CLASS-D AMPLIFIER

(71) Applicant: Texas Instruments Incorporated, Dallas, TX (US)

(72) Inventors: Sumit DUBEY, Bangalore (IN); Aditya SUNDAR, Bangalore (IN); Rushil KISHORE KUMAR, Bangalore (IN); Abhijit Anant PATKI, Bangalore (IN); Mohit CHAWLA, Bangalore (IN); Rejin K KANJAVALAPPIL RAVEENDRANATH, Bangalore (IN)

(73) Assignee: Texas Instruments Incorporated, Dallas, TX (US)

(21) Appl. No.: 19/286,692

(22) Filed: Jul. 31, 2025

(30) Foreign Application Priority Data
Oct. 24, 2024 (IN) 202441080995

(51) Int. Cl. H03F 1/02; H03F 3/217; H04R 3/04; H04R 29/00

(52) U.S. Cl. CPC H03F 1/0205; H03F 3/217; H04R 3/04; H04R 29/001; H03F 2200/03

(57) ABSTRACT

A method includes determining whether an audio signal processed in a class-D amplifier is clipping. Responsive to clipping of the audio signal, a speaker voltage is estimated as a ratio of a power supply voltage of the class-D amplifier to a resistance of a speaker driven by the class-D amplifier. An amplitude of the audio signal is controlled based on the speaker voltage.

### CROSS-REFERENCE TO RELATED APPLICATIONS

This application claims priority to Indian Provisional Application No. 202441080995, filed Oct. 24, 2024, entitled “Enhanced Mixed-Signal V-Predict Algorithm for Improving Speaker Impedance Estimation in Smart Class-D Amplifiers,” which is hereby incorporated by reference in its entirety.

### TECHNICAL FIELD

The present disclosure relates generally to an electronic system and method, and, in particular embodiments, to a class-D amplifier.

### BACKGROUND

Class-D audio amplifiers are switch mode amplifiers that typically switch at a high frequency to produce a rectangular waveform at the amplifier's output. Class-D amplifiers may be much more efficient than linear audio amplifiers, and as a result may employ smaller power supplies and eliminate heat sinks. Accordingly, class-D amplifiers may significantly reduce overall system cost, size, and weight relative to linear amplifiers of equivalent power.

### SUMMARY

In one example, an apparatus includes an audio processing circuit, a class-D amplifier, a clip detection circuit, and analog-to-digital converter (ADC), and a speaker voltage circuit. The audio processing circuit has an input configured to receive an audio input signal, and an output. The class-D amplifier has an input coupled to the output of the audio processing circuit, a supply terminal, and an output. The clip detection circuit has an input coupled to the output of the class-D amplifier, and an output. The clip detection circuit is configurable to provide a clip signal. The analog-to-digital converter (ADC) has an input coupled to the supply terminal of the class-D amplifier, and an output. The speaker voltage circuit has a first input coupled to the input of the audio processing circuit, a second input coupled to the output of the clip detection circuit, a third input coupled to the output of the ADC, and an output. The speaker voltage circuit is configured to: responsive to the clip signal having a first state, provide, at the output of the speaker voltage circuit, a speaker voltage based on the audio input signal; and responsive to the clip signal having a second state, provide, at the output of the speaker voltage circuit, the speaker voltage based on a supply voltage value provided by the ADC, the supply voltage value representing a voltage at the supply terminal of the class-D amplifier.

In another example, a method includes determining whether an audio signal processed in a class-D amplifier is clipping. Responsive to clipping of the audio signal, a speaker voltage is estimated as a ratio of a power supply voltage of the class-D amplifier to a resistance of a speaker driven by the class-D amplifier. An amplitude of the audio signal is controlled based on the speaker voltage.

In a further example, a system includes an audio processing circuit, a class-D amplifier, a clip detection circuit, a speaker voltage circuit, a controller, and an ADC. The audio processing circuit has an input and an output. The class-D amplifier has an audio input coupled to the output of the audio processing circuit, a filtered audio output, a current sense output, and an audio output. The clip detection circuit has an input coupled to the filtered audio output of the class-D amplifier, and an output. The speaker voltage circuit has a first input coupled to the input of the audio processing circuit, a second input coupled to the output of the clip detection circuit, a load resistance input, and a speaker voltage output. The controller has a speaker voltage input coupled to the speaker voltage output of the speaker voltage circuit, a current input, and a load resistance output coupled to the load resistance input of the speaker voltage circuit. The ADC has an input coupled to the current sense output of the class-D amplifier, and an output coupled to the current input of the controller.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example audio system that includes a class-D amplifier and audio amplitude control, according to an embodiment of the present disclosure;

FIG. 2 is a block diagram of an example amplitude control circuit suitable for use in the system of FIG. 1, according to an embodiment of the present disclosure;

FIG. 3 is a flow diagram of an example method of controlling audio signal amplitude in an audio system, according to an embodiment of the present disclosure;

FIG. 4 is a flow diagram for an example method of estimating speaker voltage suitable for use in the amplitude control circuit of FIG. 2 and the method of FIG. 3, according to an embodiment of the present disclosure; and

FIG. 5 is a graph of example signals in the amplitude control circuit of FIG. 2.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some systems using class-D amplifiers include amplitude control circuitry that allows the class-D amplifier to drive the speaker beyond the speaker's rated power while maintaining speaker reliability. The amplitude control circuitry may ensure that speaker temperature and excursion remain below rated maximums while delivering instantaneous power to the speaker that exceeds the speaker's rated maximum power. Temperature and excursion may be estimated based on speaker resistance. Speaker resistance may be computed based on current and voltage delivered to the speaker by the class-D amplifier. Current may be measured, and voltage may be estimated. Errors in the estimated speaker voltage can result in damage to the speaker or undue limitation of speaker output.

Some embodiments provide increased speaker voltage estimate accuracy, which may advantageously allow the class-D amplifier to increase audio amplitude without damaging the speaker.

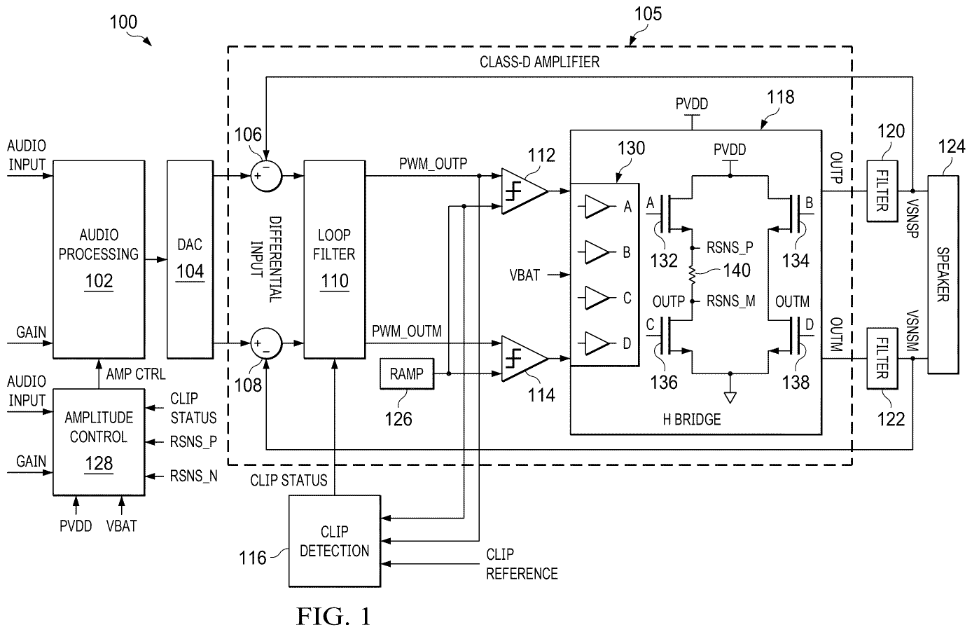

FIG. 1 is a block diagram of an example audio system 100, according to an embodiment of the present disclosure. The audio system 100 includes an audio processing circuit 102, a digital-to-analog converter (DAC) 104, a class-D amplifier 105, a clip detection circuit 116, filters 120 and 122, a speaker 124, and an amplitude control circuit 128. The audio processing circuit 102 may include up-sampling circuits that increase the sample rate of digital audio, and/or gain circuits that adjust the amplitude of digital audio. The audio processing circuit 102 has an output at which digital audio signal is provided for use by the class-D amplifier 105. The audio processing circuit 102 has a first input, at which an audio input signal (AUDIO INPUT) is received, a second input, at which a channel gain (GAIN) is received, and a third input at which an amplitude control signal (AMP CTRL) is received for use in controlling the amplitude of the digital audio signal provided to the class-D amplifier 105.

The DAC 104 converts the digital audio signal provided by the audio processing circuit 102 to analog signals for use by the class-D amplifier 105. The DAC 104 has an input coupled to the output of the audio processing circuit 102, and one or more outputs coupled to the class-D amplifier 105. The class-D amplifier 105 receives the analog audio signals provided by the DAC 104, and generates drive signals based on the analog signals to actuate the speaker 124.

The class-D amplifier 105 includes summation circuits 106 and 108, loop filter 110, comparators 112 and 114, an H-bridge circuit 118, and a ramp generator 126. The summation circuit 106 has a first input coupled to a first output of the DAC 104, a second input coupled to a first output of the class-D amplifier 105, and an output coupled to the loop filter 110. The summation circuit 108 has a first input coupled to a second output of the DAC 104, a second input coupled to a second output of the class-D amplifier 105, and an output coupled to the loop filter 110. The summation circuits 106 and 108 subtract the output of the class-D amplifier 105 from the analog audio signal received from the DAC 104 to produce an error signal that is provided to the loop filter 110. The loop filter 110 may filter frequencies outside a frequency range of interest (e.g., frequencies greater than 20 kilohertz), and amplifies frequencies in the audio band (e.g., 20 hertz to 20 kilohertz). The loop filter 110 has a first output at which an analog signal PWM_OUTP is provided, and a second output at which an analog signal PWM_OUTN is provided.

The comparators 112 and 114 are coupled to the first and second outputs of the loop filter 110. The comparators 112 and 114 generate pulse width modulation (PWM) control signals that control switching of the H-bridge circuit 118. The comparator 112 has a first input coupled to a first output of the loop filter 110, a second input coupled to an output of the ramp generator 126, and an output coupled to the H-bridge circuit 118. The comparator 114 has a first input coupled to the second output of the loop filter 110, a second input coupled to the output of the ramp generator 126, and an output coupled to the H-bridge circuit 118. The ramp generator 126 generates a ramp signal for use by the comparators 112 and 114. The comparators 112 and 114 compare PWM_OUTP and PWM_OUTN to the ramp signal provided by the ramp generator 126 to generate the PWM control signals provided to the H-bridge circuit 118.

The H-bridge circuit 118 includes drivers 130, transistors 132, 134, 136, and 138, and a current sensor 140. The current sensor 140 may be a sense resistor. The transistors 132, 134, 136, and 138 may be n-channel field effect transistors (NFETs) connected as an H-bridge. Drain terminals of the high-side transistors (e.g., transistors 132 and 134) may be coupled to a power supply terminal PVDD for receipt of a power supply voltage PVDD. Source terminals of the low-side transistors (e.g., transistors 136 and 138) may be coupled to a reference terminal (e.g., ground). A source terminal of the transistor 132 may be coupled to a drain terminal of the transistor 136 via the current sensor 140, and a source terminal of the transistor 134 may be coupled to a drain terminal of the transistor 138. A first output of the H-bridge circuit 118, at which signal OUTP is provided, is coupled to the drain terminal of the transistor 136, and a second output of the H-bridge circuit 118, which signal OUTN is provided, is coupled to the drain terminal of the transistor 138.

The voltage across the current sensor 140 represents the current flowing from the H-bridge circuit 118 to actuate the speaker 124. Signal RSNS_P is provided at a first terminal of the current sensor 140, and signal RSNS_N is provided at a second terminal of the current sensor 140. The difference in voltage of RSNS_P and RSNS_N (the voltage across the current sensor 140) may be determined to measure the current flowing to the speaker 124.

The drivers 130 includes gate driver circuits that have outputs coupled to the gates of the transistors 132, 134, 136, and 138 to control switching thereof. The H-bridge circuit 118 has a driver bias terminal (VBAT) for receipt of a driver bias voltage used to power the gate drivers controlling the high-side transistors (e.g., transistors 132 and 134). Inputs of the gate driver circuits may be derived from the PWM signals received form the comparators 112 and 114.

The filters 120 and 122 are coupled between outputs of the class-D amplifier 105 and the terminals of the speaker 124. The filters 120 and 122 are low-pass filters that attenuate the higher frequencies produced by switching of the transistors 132, 134, 136, and 138. The filter 120 and the filter 122 may be L-C filters in some examples.

The clip detection circuit 116 monitors the output of the loop filter 110 to determine whether the output signal of the class-D amplifier 105 is clipped. The clip detection circuit 116 may include comparators that compare the PWM_OUTP and PWM_OUTM to a clip threshold (CLIP REFERENCE). CLIP REFERENCE may be set to a voltage that is slightly higher or slightly lower than the peak voltage of the ramp signal provided by the ramp generator 126. If PWM_OUTP or PWM_OUTM exceeds CLIP REFERENCE, then the clip detection circuit 116 sets an output signal (a clip signal CLIP STATUS) to a state indicating clipping. If PWM_OUTP and PWM_OUTM do not exceed CLIP REFERENCE, then the clip detection circuit 116 sets CLIP STATUS to a state indicating no clipping. The clip detection circuit 116 has first and second inputs respectively coupled to the first and second outputs of the loop filter 110 (a first and second filtered audio output of the class-D amplifier 105). The clip detection circuit 116 has a third input for receiving CLIP REFERENCE. In some examples, the third input of the clip detection circuit 116 may be coupled to an output of the ramp generator 126 at which CLIP REFERENCE is provided. The clip detection circuit 116 has an output, at which CLIP STATUS is provided, coupled to an input of the loop filter 110. The loop filter 110 may reset stored history responsive to CLIP STATUS indicating that class-D output signal is clipped.

The amplitude control circuit 128 has an input coupled to PVDD, an input coupled to VBAT, inputs coupled to the first and second terminals of the current sensor 140, an input coupled to the output of the clip detection circuit 116, inputs coupled to the first and second inputs of the audio processing circuit 102, and an output coupled to the audio processing circuit 102. The amplitude control circuit 128 estimates the resistance of the speaker 124, and adjusts the amplitude of the audio signal provided by the audio processing circuit 102 based on the estimated resistance of the speaker 124. The amplitude control circuit 128 estimates the resistance of the speaker 124 based on the current sensed by the current sensor 140, and an estimated voltage across the speaker 124. The amplitude control circuit 128 estimates the voltage across the speaker based on the audio input signal and channel gain if CLIP STATUS indicates that that output of the class-D amplifier 105 is not clipping. The amplitude control circuit 128 estimates speaker voltage based on the voltage at PVDD, the estimated resistance of the speaker 124, and the on-resistance of the transistors 132, 134, 136, and 138 if CLIP STATUS indicates that the output of the class-D amplifier 105 is clipping. By estimating speaker voltage based on PVDD voltage, speaker resistance, and transistor on-resistance, the amplitude control circuit 128 can provide speaker voltage values that are more accurate than the estimates provided using other methods. More accurate speaker voltage values can produce more accurate speaker resistance values, and better control of the signals provided to drive the speaker 124.

In some embodiments, audio processing circuit 102 may be implemented using a custom or generic processor or controller coupled to a memory and configured to execute instructions in such memory. In some embodiments, audio processing circuit 102 may be implemented with a field programmable gate array (FPGA). In some embodiments, audio processing circuit 102 includes a state machine. In some embodiments, audio processing circuit 102 be implemented or include synthesized logic. Other implementations may also be possible.

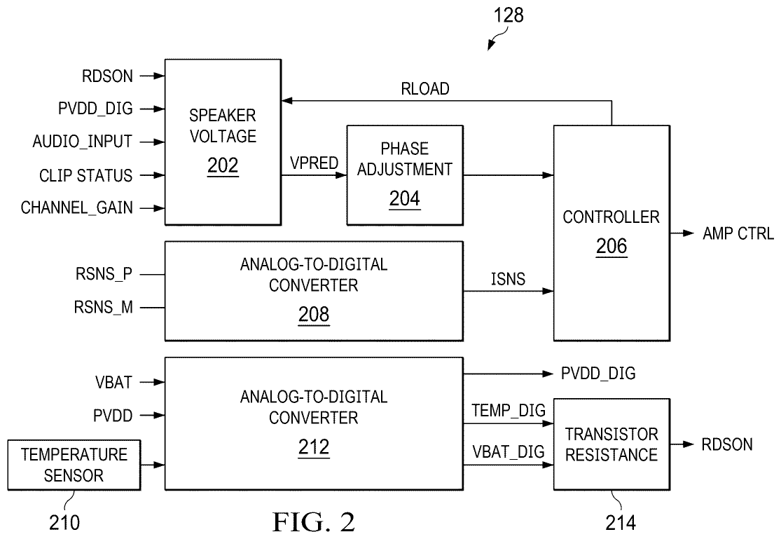

FIG. 2 is a block diagram of an example of the amplitude control circuit 128, according to an embodiment of the present disclosure. The amplitude control circuit 128 includes a speaker voltage circuit 202, a phase adjustment circuit 204, a controller 206, an analog-to-digital converter (ADC) 208, a temperature sensor 210, an ADC 212, and a transistor resistance circuit 214. The ADC 208 has inputs coupled to the first and second terminals of the current sensor 140 (a first and second current sense output of the class-D amplifier 105) for receipt of RSNS_P and RSNS_N. The ADC 208 digitizes the difference of RSNS_P and RSNS_N, and provides a current value ISNS representing the current flowing through the current sensor 140 to drive the speaker 124. The ADC 208 has an output coupled to the controller 206 for providing ISNS to the controller 206.

The ADC 212 digitizes various signals used in the amplitude control circuit 128. The ADC 212 has a first input coupled to PVDD, a second input coupled to VBAT, and a third input coupled to the temperature sensor 210. The temperature sensor 210 senses the temperature of the class-D amplifier 105 (e.g., the temperature of the transistors 132, 134, 136, and 138). The ADC 212 digitizes the voltage at PVDD, the voltage at VBAT, and a temperature signal provided by the temperature sensor 210 for use in estimating speaker voltage.

The transistor resistance circuit 214 determines the runtime on-resistance of the transistors 132, 134, 136, and 138 for use in speaker voltage estimation. The transistor resistance circuit 214 may compute the runtime on-resistance based on transistor parameters (e.g., on-resistance, threshold voltage, etc.) measured at manufacture, runtime temperature, and driver bias voltage measured at runtime. Some examples of the transistor resistance circuit 214 may determine the transistor on-resistance as:

$$Rdson = \frac{{R}_{o} ( {a}_{0} {Temp}^{2} + {a}_{1} Temp + {a}_{2} )}{K ( VBAT - Vth )} \qquad ( 1 )$$

where:
Rdson is on-resistance of the transistors 132, 134, 136, and 138 in operation;
Rₒ is a value of on-resistance of the transistors 132, 134, 136, and 138 measured at manufacture;
Temp is measured temperature of the class-D amplifier 105 measured by the temperature sensor 210;
VBAT is measured transistor driver bias voltage at the VBAT terminal provided to the drivers 130;
Vth is threshold voltage of the transistors 132, 134, 136, and 138 measured at manufacture; and
a₀, a₁, a₂, and K are process dependent coefficients.

In some examples of the transistor resistance circuit 214, some of the coefficients (e.g., a₀, a₁, and/or a₂) may be set to zero to reduce computational complexity.

The speaker voltage circuit 202 estimates speaker voltage based on the operational conditions of the class-D amplifier 105. The speaker voltage circuit 202 has a speaker voltage output, at which an estimated speaker voltage (VPRED) is provided. The speaker voltage circuit 202 has a first input coupled to the first input of the audio processing circuit 102 (e.g., the audio input of the audio processing circuit 102) for receipt of the audio input signal. The speaker voltage circuit 202 has a second input coupled to the second input of the audio processing circuit 102 (e.g., the gain input of the audio processing circuit 102) for receipt of the channel gain signal. The speaker voltage circuit 202 has a third input coupled to the output of the clip detection circuit 116 for receipt of CLIP STATUS. The speaker voltage circuit 202 has a fourth input coupled to the output of the ADC 212 for receipt of PVDD_DIG. The speaker voltage circuit 202 has a fifth input coupled to the on-resistance output of the transistor resistance circuit 214 for receipt of RDSON. The speaker voltage circuit 202 has a sixth input (a load resistance input) coupled to a load resistance output of the controller 206. Examples of the speaker voltage circuit 202 may estimate speaker voltage based on the audio input signal and the channel gain responsive to CLIP STATUS indicating that the output signal of the class-D amplifier 105 is not clipping. For example, responsive CLIP STATUS indicating that the output signal of the class-D amplifier 105 is not clipping, the speaker voltage circuit 202 may compute speaker voltage as:

$$VPRED = AudioInput * Gain \qquad ( 2 )$$

where:
VPRED is the speaker voltage estimated by the speaker voltage circuit 202;
AudioInput is the audio input signal; and
Gain is the channel gain.

Examples of the speaker voltage circuit 202 may estimate speaker voltage based on the voltage at PVDD, the estimated speaker resistance, and transistor on-resistance responsive to CLIP STATUS indicating that the output signal of the class-D amplifier 105 is clipping. For example, responsive CLIP STATUS indicating that the output signal of the class-D amplifier 105 is clipping, the speaker voltage circuit 202 may compute speaker voltage as the ratio:

$$VPRED = \frac{PVDD * RLOAD}{RLOAD + RDSON} \qquad ( 3 )$$

where:
VPRED is the speaker voltage estimated by the speaker voltage circuit 202;
PVDD is a supply voltage value provided by the ADC 212 representing the voltage at the PVDD terminal;
RLOAD is the estimated resistance of the speaker 124 (load resistance); and
RDSON is an on-resistance of transistors 132, 134, 136, and 138 computed by the transistor resistance circuit 214.

Accordingly, if the output signal of the class-D amplifier 105 is not clipped, then the estimated speaker voltage is based on the input audio signal and channel gain. If the output signal of the class-D amplifier 105 is clipped, then the speaker voltage is based on the power supply voltages provided to the H-bridge circuit 118, the estimated speaker resistance, and the estimated on-resistance of the transistors 132, 134, 136, and 138. By computing speaker voltage according to Equation (3) during clipping, the speaker voltage circuit 202 provides more accurate values of speaker voltage than are provided using other methods.

The speaker voltage circuit 202 has an output at which VPRED is provided. The output of the speaker voltage circuit 202 is coupled to an input of the phase adjustment circuit 204. The phase adjustment circuit 204 adjusts the phase of the VPRED signal received from the speaker voltage circuit 202 such that values of VPRED are time aligned with values of ISNS provided by the ADC 208. For example, the phase adjustment circuit 204 may delay values of VPRED by a time corresponding to the latency of the ADC 208 to align VPRED with ISNS. The phase adjustment circuit 204 has an output at which phase adjusted VPRED is provided.

The controller 206 controls attenuation of the audio input signal by the audio processing circuit 102 to provide as much volume from the speaker as possible, while avoiding speaker damage. Control of attenuation is based on estimated speaker resistance. The controller 206 has a speaker voltage input coupled to the output of the phase adjustment circuit 204, and a current input coupled to the output of the ADC 208. The controller 206 has a load resistance output coupled to an input of the speaker voltage circuit 202, and an amplitude control output coupled to an input of the audio processing circuit 102.

The controller 206 estimates speaker resistance based on VPRED and ISNS. For example, the controller 206 may estimate speaker resistance as:

$$RLOAD = \frac{VPRED}{ISNS} \qquad ( 4 )$$

Accurate values of speaker voltage provided by the speaker voltage circuit 202 during clipping, allow the controller 206 to provide more accurate estimations of speaker resistance, and improved control of audio signal amplitude based on speaker conditions. Based on the speaker resistance, the controller 206 can estimate speaker temperature and excursion (e.g., in ways known in the art) and provide the control signal AMP CTRL to set attenuation as needed in the audio processing circuit 102 to avoid speaker excursion and temperature that exceed selected thresholds. Accordingly, the amplitude control circuit 128 allows speaker volume to be maximized, while avoiding speaker damage.

The various operations of the amplitude control circuit 128 may be performed on a sample-by-sample basis. For each sample of the audio input signal, a new value of VPRED, ISNS, RLOAD, and AMP CNTRL may be generated by the speaker voltage circuit 202, the ADC 208, and the controller 206. Accordingly, the amplitude control circuit 128 controls the amplitude of the audio signal provided to the class-D amplifier 105 on a sample-by-sample basis.

In examples of the amplitude control circuit 128, the speaker voltage circuit 202, the phase adjustment circuit 204, the controller 206, and/or the transistor resistance circuit 214 may be implemented in various ways. In some examples of the amplitude control circuit 128, the speaker voltage circuit 202, the phase adjustment circuit 204, the controller 206, and/or the transistor resistance circuit 214 may be implemented as hardware circuitry configured to provide the functionality described herein. Alternatively, the speaker voltage circuit 202, the phase adjustment circuit 204, the controller 206, and/or the transistor resistance circuit 214 may be implemented using a processor that executes instructions to perform the functionality described herein.

In some embodiments, controller 206 may be implemented using a custom or generic processor or controller coupled to a memory and configured to execute instructions in such memory. In some embodiments, controller 206 may be implemented with a field programmable gate array (FPGA). In some embodiments, controller 206includes a state machine. In some embodiments, controller 206be implemented or include synthesized logic. Other implementations may also be possible.

In some embodiments, controller 206 may be implemented separate from audio processing circuit 102. In some embodiments, controller 206 may be implemented as part of audio processing circuit 102.

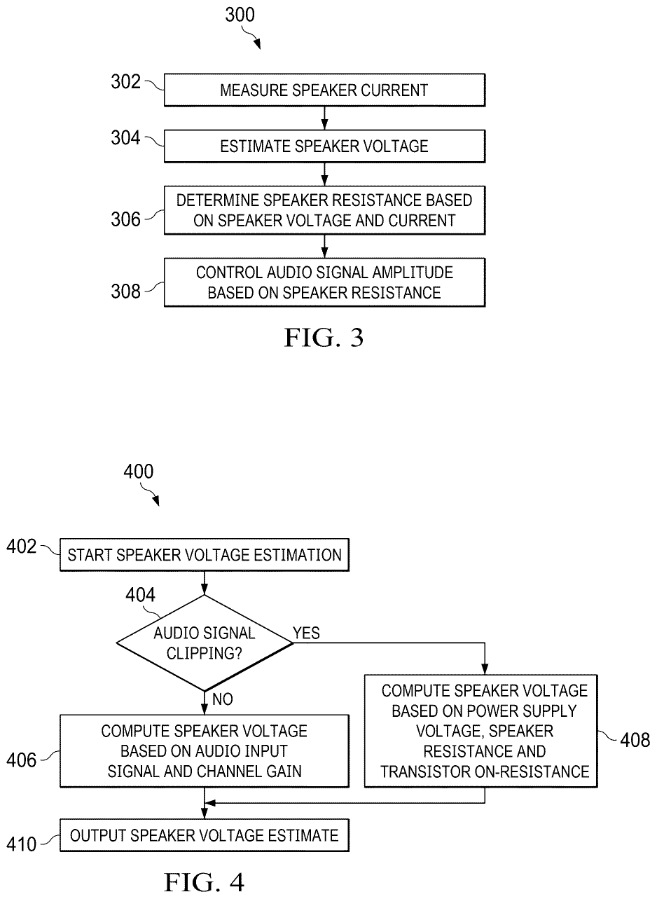

FIG. 3 is a flow diagram of an example method 300 of controlling audio signal amplitude in an audio system, according to an embodiment of the present disclosure. Though depicted sequentially as a matter of convenience, at least some of the actions shown can be performed in a different order and/or performed in parallel. Additionally, some implementations may perform only some of the actions shown. Operations of the method 300 may be performed by an example of the amplitude control circuit 128. In the method 300, the audio system 100 is driving the speaker 124 based on the audio input signal provided to the audio processing circuit 102.

In block 302, current flowing through the speaker 124 is measured. For example, the current flowing through the speaker 124 flows through the current sensor 140, and a voltage across the current sensor 140 is digitized by the ADC 208.

In block 304, the voltage across the speaker 124 is estimated. For example, the speaker voltage circuit 202 estimates the voltage across the speaker as described herein.

In block 306, speaker resistance is estimated based on the current measured in block 302, and speaker voltage estimated in block 304. The controller 206 may determine the speaker resistance, and provide the speaker resistance to the speaker voltage circuit 202 for use in estimating speaker voltage for a subsequent audio sample.

In block 308, the amplitude of the audio input signal provided to the class-D amplifier 105 is adjusted based on the speaker resistance determined in block 306. For example, an increase in speaker resistance may indicate that speaker temperature has increased. In response to the increase in speaker resistance, the controller 206 may set the AMP CTRL signal to specify an amount of attenuation to be applied to the audio input signal. The audio processing circuit 102 attenuates the audio input signal responsive to AMP CTRL to protect the speaker 124.

FIG. 4 is a flow diagram for an example method 400 of estimating speaker voltage suitable for use in the speaker voltage circuit 202 and the method 300, according to an embodiment of the present disclosure. Though depicted sequentially as a matter of convenience, at least some of the actions shown can be performed in a different order and/or performed in parallel. Additionally, some implementations may perform only some of the actions shown.

In block 402, the speaker voltage circuit 202 receives the audio input, channel gain, and clip status signals. The clip status signal may be provided by the clip detection circuit 116. The clip status signal indicates whether the drive signal (OUTP, OUTM) provided by the class-D amplifier 105 is clipped.

In block 404, if the clip status signal indicates that the drive signal output by the class-D amplifier 105 is not clipped, then in block 406, the speaker voltage circuit 202 computes the speaker voltage based on the audio input signal and the channel gain. For example, the speaker voltage circuit 202 may compute the speaker voltage as in equation (2).

In block 404, if the clip status signal indicates that the drive signal output by the class-D amplifier 105 is clipped, then in block 408, the speaker voltage circuit 202 computes the speaker voltage based on the voltage at PVDD (power supply voltage), the resistance of the speaker 124, and the on-resistance of the transistors 132, 134, 136, and 138. For example, the speaker voltage circuit 202 may compute the speaker voltage as in equation (3).

In block 410, the speaker voltage circuit 202 outputs the speaker voltage computed in block 406 or block 408 for use in computing speaker resistance by the controller 206.

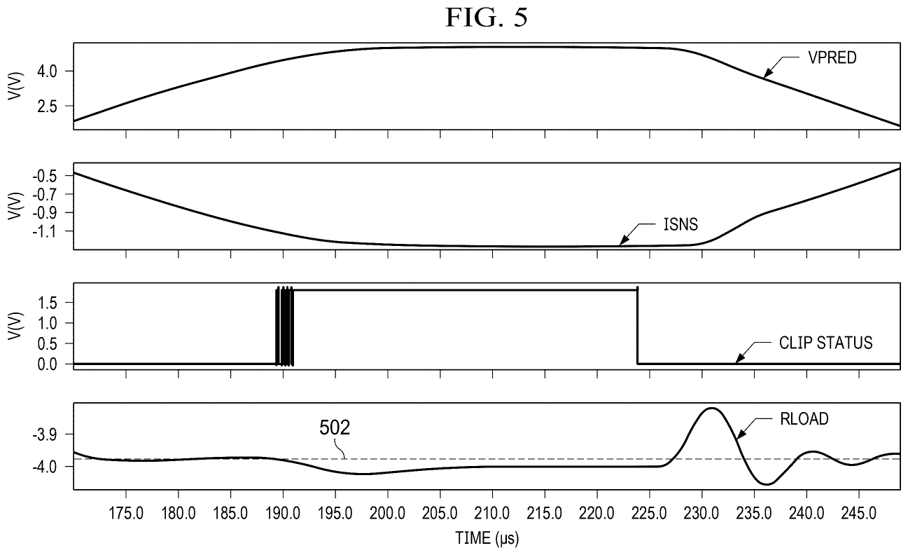

FIG. 5 is a graph of example signals in the amplitude control circuit 128, according to an embodiment of the present disclosure. The estimated speaker voltage (VPRED), measured speaker current (ISNS), estimated speaker resistance (RLOAD), and CLIP STATUS signals are shown in FIG. 5. CLIP STATUS indicates that the output of the class-D amplifier 105 is clipping from about 190 microseconds to about 225 microseconds. During this interval, the speaker voltage circuit 202 computes VPRED using equation (3). Prior to and after this interval, the speaker voltage circuit 202 computes VPRED using equation (2).

In FIG. 5, the line 502 represents the actual resistance of the speaker 124. The error in the speaker resistance (RLOAD) computed based on VPRED and ISNS using the method 400 is less than 0.5% during clipping. The error in RLOAD produced using previously applied methods may be no better than about 4%. Accordingly, FIG. 5 shows that the speaker voltage estimation disclosed herein may advantageously provide significantly more accurate speaker resistance estimates than known methods. The more accurate speaker resistance estimates enable better control of audio amplitude for providing higher speaker output, and protection from speaker damage.

Example embodiments of the present disclosure are summarized here. Other embodiments can also be understood from the entirety of the specification and the claims filed herein.

Example 1. An apparatus including: an audio processing circuit having an input configured to receive an audio input signal, and an output; a class-D amplifier having an input coupled to the output of the audio processing circuit, a supply terminal, and an output; a clip detection circuit having an input coupled to the output of the class-D amplifier, and an output, the clip detection circuit configurable to provide a clip signal; an analog-to-digital converter (ADC) having an input coupled to the supply terminal of the class-D amplifier, and an output; a speaker voltage circuit having a first input coupled to the input of the audio processing circuit, a second input coupled to the output of the clip detection circuit, a third input coupled to the output of the ADC, and an output, the speaker voltage circuit configured to: responsive to the clip signal having a first state, provide, at the output of the speaker voltage circuit, a speaker voltage based on the audio input signal; and responsive to the clip signal having a second state, provide, at the output of the speaker voltage circuit, the speaker voltage based on a supply voltage value provided by the ADC, the supply voltage value representing a voltage at the supply terminal of the class-D amplifier.

Example 2. The apparatus of example 1, where the speaker voltage circuit has a fourth input, where the class-D amplifier includes a current sensor having an output, and where the ADC is a first ADC, the apparatus further including: a second ADC having an input coupled to the output of the current sensor, and an output; and a controller having a first input coupled to the output of the speaker voltage circuit, a second input coupled to the output of the second ADC, and an output coupled to the fourth input of the speaker voltage circuit, where the controller is configured to determine a value of load resistance driven by the class-D amplifier based on the speaker voltage and a current value provided by the second ADC.

Example 3. The apparatus of one of examples 1 or 2, further including a phase adjustment circuit having an input coupled to the output of the speaker voltage circuit, and an output coupled to the first input of the controller.

Example 4. The apparatus of one of examples 1 to 3, where the speaker voltage circuit is configured to, responsive to the clip signal having the second state, provide, at the output of the speaker voltage circuit, the speaker voltage based on the value of load resistance.

Example 5. The apparatus of one of examples 1 to 4, further including a transistor resistance circuit configured to determine an on-resistance of one or more transistors of the class-D amplifier.

Example 6. The apparatus of one of examples 1 to 5, where: the apparatus includes a temperature sensor; and the transistor resistance circuit is configured to determine the on-resistance of the one or more transistors based on a temperature signal provided by the temperature sensor.

Example 7. The apparatus of one of examples 1 to 6, where: the class-D amplifier includes a gate driver having an output coupled to a control terminal of at least one of the one or more transistors, and a supply terminal configured to receive a driver bias voltage for powering the gate driver; and the transistor resistance circuit is configured to determine the on-resistance of transistors based on the driver bias voltage.

Example 8. The apparatus of one of examples 1 to 7, where the transistor resistance circuit is configured to determine the resistance of the one or more transistors as:

$$Rdson = \frac{{R}_{o} ( {a}_{0} {Temp}^{2} + {a}_{1} Temp + {a}_{2} )}{K ( VBAT - Vth )}$$

where: Rdson represents the on-resistance of the one or more transistors; Ro represents a nominal value of on-resistance of the one or more transistors; Temp represents a measured temperature of the class-D amplifier; VBAT represents a measured transistor driver bias voltage of the class-D amplifier; and a0, a1, a2, and K represent coefficients.

Example 9. The apparatus of one of examples 1 to 8, where the speaker voltage circuit is configured to, responsive to the clip signal having the second state, provide, at the output of the speaker voltage circuit, the speaker voltage based on the on-resistance of the one or more transistors of the class-D amplifier.

Example 10. The apparatus of one of examples 1 to 9, where the speaker voltage circuit is configured to, responsive to the clip signal having the second state, provide, at the output of the speaker voltage circuit, the speaker voltage as:

$$VPRED = \frac{PVDD * RLOAD}{RLOAD + RDSON}$$

where: VPRED represents the speaker voltage (a voltage between terminals of a speaker); PVDD represents a voltage at the supply terminal of the class-D amplifier; RLOAD represents a resistance of a load driven the class-D amplifier; and RDSON represents an on-resistance of one or more transistors of the class-D amplifier.

Example 11. A method including: determining whether an audio signal processed in a class-D amplifier is clipping; responsive to clipping of the audio signal, estimating a speaker voltage as a ratio of a power supply voltage of the class-D amplifier to a resistance of a speaker driven by the class-D amplifier; and controlling an amplitude of the audio signal based on the speaker voltage.

Example 12. The method of example 11, further including: measuring a current provided to the speaker by the class-D amplifier, and estimating the resistance of the speaker based on the current and the speaker voltage.

Example 13. The method of one of examples 11 or 12, further including estimating the resistance of the speaker as:

$$RLOAD = \frac{VPRED}{ISNS}$$

where: RLOAD represents the resistance of the speaker; VPRED represents the speaker voltage; and ISNS represents the current provided to the speaker.

Example 14. The method of one of examples 11 to 13, further including: determining an on-resistance of transistors of the class-D amplifier; and estimating the speaker voltage based on the on-resistance of the transistors.

Example 15. The method of one of examples 11 to 14, further including estimating the speaker voltage as:

$$VPRED = \frac{PVDD * RLOAD}{RLOAD + RDSON}$$

where: VPRED represents the speaker voltage (a voltage between terminals of the speaker); PVDD represents power supply voltage of the class-D amplifier; RLOAD represents resistance of the speaker; and RDSON represents an on-resistance of transistors of the class-D amplifier.

Example 16. The method of one of examples 11 to 15, further including estimating the on-resistance as:

$$Rdson = \frac{{R}_{o} ( {a}_{0} {Temp}^{2} + {a}_{1} Temp + {a}_{2} )}{K ( VBAT - Vth )}$$

where: Rdson represents on-resistance of the one or more transistors; Ro represents an on-resistance of the transistors measured at manufacture; Temp represents a measured temperature of the class-D amplifier; VBAT represents a measured transistor driver bias voltage of the class-D amplifier; and a0, a1, a2, and K are process dependent coefficients.

Example 17. A system including: an audio processing circuit having an input and an output; a class-D amplifier having an audio input coupled to the output of the audio processing circuit, a filtered audio output, a current sense output, and an audio output; a clip detection circuit having an input coupled to the filtered audio output of the class-D amplifier, and an output; a speaker voltage circuit having a first input coupled to the input of the audio processing circuit, a second input coupled to the output of the clip detection circuit, a load resistance input, and a speaker voltage output; a controller having a speaker voltage input coupled to the speaker voltage output of the speaker voltage circuit, a current input, and a load resistance output coupled to the load resistance input of the speaker voltage circuit; and an analog-to-digital converter (ADC) having an input coupled to the current sense output of the class-D amplifier, and an output coupled to the current input of the controller.

Example 18. The system of example 17, where: the controller has an amplitude control output; the input of the audio processing circuit is a first input; the audio processing circuit has a second input, and third input coupled to the amplitude control output; the speaker voltage circuit has a third input coupled to the second input of the audio processing circuit; and the system includes a digital-to-analog converter (DAC) having an input coupled to the output of the audio processing circuit and an output coupled to the input of the class-D amplifier.

Example 19. The system of one of examples 17 or 18, where the class-D amplifier has a power supply terminal, and where the ADC is a first ADC, the system further including a second ADC having a first input coupled to the power supply terminal, and an output, where the speaker voltage circuit has a third input coupled to the output of the second ADC.

Example 20. The system of one of examples 17 to 19, where the speaker voltage circuit has a fourth input, where the class-D amplifier has a driver bias terminal, and where the second ADC has a second input, and a third input coupled to the driver bias terminal, the system further including: a temperature sensor having an output coupled to the second input of the second ADC; a transistor resistance circuit having an input coupled to the output of the second ADC, and an on-resistance output coupled to the fourth input of the speaker voltage circuit.

Example 21. The system of one of examples 17 to 20, further including a speaker coupled to the audio output of the class-D amplifier.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Unless otherwise stated, “about,” “approximately” or “substantially” preceding a parameter means being within +/−10 percent of that parameter or, if the parameter is zero, a reasonable range of values around zero.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
an audio processing circuit having an input configured to receive an audio input signal, and an output;
a class-D amplifier having an input coupled to the output of the audio processing circuit, a supply terminal, and an output;
a clip detection circuit having an input coupled to the output of the class-D amplifier, and an output, the clip detection circuit configurable to provide a clip signal;
an analog-to-digital converter (ADC) having an input coupled to the supply terminal of the class-D amplifier, and an output;
a speaker voltage circuit having a first input coupled to the input of the audio processing circuit, a second input coupled to the output of the clip detection circuit, a third input coupled to the output of the ADC, and an output, the speaker voltage circuit configured to:
responsive to the clip signal having a first state, provide, at the output of the speaker voltage circuit, a speaker voltage based on the audio input signal; and
responsive to the clip signal having a second state, provide, at the output of the speaker voltage circuit, the speaker voltage based on a supply voltage value provided by the ADC, the supply voltage value representing a voltage at the supply terminal of the class-D amplifier.

2. The apparatus of claim 1, wherein the speaker voltage circuit has a fourth input, wherein the class-D amplifier includes a current sensor having an output, and wherein the ADC is a first ADC, the apparatus further including:
a second ADC having an input coupled to the output of the current sensor, and an output; and
a controller having a first input coupled to the output of the speaker voltage circuit, a second input coupled to the output of the second ADC, and an output coupled to the fourth input of the speaker voltage circuit, wherein the controller is configured to determine a value of load resistance driven by the class-D amplifier based on the speaker voltage and a current value provided by the second ADC.

3. The apparatus of claim 2, further comprising a phase adjustment circuit having an input coupled to the output of the speaker voltage circuit, and an output coupled to the first input of the controller.

4. The apparatus of claim 2, wherein the speaker voltage circuit is configured to, responsive to the clip signal having the second state, provide, at the output of the speaker voltage circuit, the speaker voltage based on the value of load resistance.

5. The apparatus of claim 1, further comprising a transistor resistance circuit configured to determine an on-resistance of one or more transistors of the class-D amplifier.

6. The apparatus of claim 5, wherein:
the apparatus includes a temperature sensor; and
the transistor resistance circuit is configured to determine the on-resistance of the one or more transistors based on a temperature signal provided by the temperature sensor.

7. The apparatus of claim 6, wherein:
the class-D amplifier includes a gate driver having an output coupled to a control terminal of at least one of the one or more transistors, and a supply terminal configured to receive a driver bias voltage for powering the gate driver; and
the transistor resistance circuit is configured to determine the on-resistance of transistors based on the driver bias voltage.

8. The apparatus of claim 5, wherein the transistor resistance circuit is configured to determine the resistance of the one or more transistors as:
$$Rdson = \frac{{R}_{o} ( {a}_{0} {Temp}^{2} + {a}_{1} Temp + {a}_{2} )}{K ( VBAT - Vth )}$$
wherein:
Rdson represents the on-resistance of the one or more transistors;
Rₒ represents a nominal value of on-resistance of the one or more transistors;
Temp represents a measured temperature of the class-D amplifier;
VBAT represents a measured transistor driver bias voltage of the class-D amplifier; and
a₀, a₁, a₂, and K represent coefficients.

9. The apparatus of claim 5, wherein the speaker voltage circuit is configured to, responsive to the clip signal having the second state, provide, at the output of the speaker voltage circuit, the speaker voltage based on the on-resistance of the one or more transistors of the class-D amplifier.

10. The apparatus of claim 1, wherein the speaker voltage circuit is configured to, responsive to the clip signal having the second state, provide, at the output of the speaker voltage circuit, the speaker voltage as:
$$VPRED = \frac{PVDD * RLOAD}{RLOAD + RDSON}$$
wherein:
VPRED represents the speaker voltage (a voltage between terminals of a speaker);
PVDD represents a voltage at the supply terminal of the class-D amplifier;
RLOAD represents a resistance of a load driven the class-D amplifier; and
RDSON represents an on-resistance of one or more transistors of the class-D amplifier.

11. A method comprising:
determining whether an audio signal processed in a class-D amplifier is clipping;
responsive to clipping of the audio signal, estimating a speaker voltage as a ratio of a power supply voltage of the class-D amplifier to a resistance of a speaker driven by the class-D amplifier; and
controlling an amplitude of the audio signal based on the speaker voltage.

12. The method of claim 11, further comprising:
measuring a current provided to the speaker by the class-D amplifier, and
estimating the resistance of the speaker based on the current and the speaker voltage.

13. The method of claim 12, further comprising estimating the resistance of the speaker as:
$$RLOAD = \frac{VPRED}{ISNS}$$
wherein:
RLOAD represents the resistance of the speaker;
VPRED represents the speaker voltage; and
ISNS represents the current provided to the speaker.

14. The method of claim 12, further comprising:
determining an on-resistance of transistors of the class-D amplifier; and
estimating the speaker voltage based on the on-resistance of the transistors.

15. The method of claim 14, further comprising estimating the speaker voltage as:
$$VPRED = \frac{PVDD * RLOAD}{RLOAD + RDSON}$$
wherein:
VPRED represents the speaker voltage (a voltage between terminals of the speaker);
PVDD represents power supply voltage of the class-D amplifier;
RLOAD represents resistance of the speaker; and
RDSON represents an on-resistance of transistors of the class-D amplifier.

16. The method of claim 14, further comprising estimating the on-resistance as:
$$Rdson = \frac{{R}_{o} ( {a}_{0} {Temp}^{2} + {a}_{1} Temp + {a}_{2} )}{K ( VBAT - Vth )}$$
wherein:
Rdson represents on-resistance of the one or more transistors;
Rₒ represents an on-resistance of the transistors measured at manufacture;
Temp represents a measured temperature of the class-D amplifier;
VBAT represents a measured transistor driver bias voltage of the class-D amplifier; and
a₀, a₁, a₂, and K are process dependent coefficients.

17. A system comprising:
an audio processing circuit having an input and an output;
a class-D amplifier having an audio input coupled to the output of the audio processing circuit, a filtered audio output, a current sense output, and an audio output;
a clip detection circuit having an input coupled to the filtered audio output of the class-D amplifier, and an output;
a speaker voltage circuit having a first input coupled to the input of the audio processing circuit, a second input coupled to the output of the clip detection circuit, a load resistance input, and a speaker voltage output;
a controller having a speaker voltage input coupled to the speaker voltage output of the speaker voltage circuit, a current input, and a load resistance output coupled to the load resistance input of the speaker voltage circuit; and
an analog-to-digital converter (ADC) having an input coupled to the current sense output of the class-D amplifier, and an output coupled to the current input of the controller.

18. The system of claim 17, wherein:
the controller has an amplitude control output;
the input of the audio processing circuit is a first input;
the audio processing circuit has a second input, and third input coupled to the amplitude control output;
the speaker voltage circuit has a third input coupled to the second input of the audio processing circuit; and
the system includes a digital-to-analog converter (DAC) having an input coupled to the output of the audio processing circuit and an output coupled to the input of the class-D amplifier.

19. The system of claim 17, wherein the class-D amplifier has a power supply terminal, and wherein the ADC is a first ADC, the system further including a second ADC having a first input coupled to the power supply terminal, and an output, wherein the speaker voltage circuit has a third input coupled to the output of the second ADC.

20. The system of claim 19, wherein the speaker voltage circuit has a fourth input, wherein the class-D amplifier has a driver bias terminal, and wherein the second ADC has a second input, and a third input coupled to the driver bias terminal, the system further including:
a temperature sensor having an output coupled to the second input of the second ADC;
a transistor resistance circuit having an input coupled to the output of the second ADC, and
an on-resistance output coupled to the fourth input of the speaker voltage circuit.

21. The system of claim 17, further comprising a speaker coupled to the audio output of the class-D amplifier.
